(19) United States
(12) Patent Application Publication
(10) Pub. No.: US 2026/0130021 A1
(43) Pub. Date: May 7, 2026

(54) Apparatus for Manufacturing Display Panel

(71) Applicant: LG Display Co., Ltd., Seoul (KR)

(72) Inventors: Youngsuk Hwang, Anyang-si (KR); Doyoung Kwak, Hanam-si (KR)

(21) Appl. No.: 19/185,879

(22) Filed: Apr. 22, 2025

(30) Foreign Application Priority Data
Nov. 6, 2024 (KR) 10-2024-0156012

(51) Int. Cl. H10H 29/03; H10H 29/01

(52) U.S. Cl. CPC H10H 29/03; H10H 29/0364

(57) ABSTRACT

The present disclosure relates to an apparatus for manufacturing a display panel in which it is possible to prevent light-emitting elements from remaining on a transfer member during a transfer process, thereby preventing damage to a donor member or a panel defect. To achieve this, in the apparatus for manufacturing a display panel, by allowing the light-emitting members that remain on the transfer member during the transfer process to be adhered to a maintenance wafer substrate, it is possible to remove the light-emitting elements that remain on the transfer member. Accordingly, by removing the light-emitting elements that remain on the transfer member during the transfer process, it is possible to prevent damage to the donor member or the panel defect.

### CROSS REFERENCE TO RELATED APPLICATION

Pursuant to 35 U.S.C. § 119(a), this application claims the benefit of an earlier filing date and right of priority to Republic of Korea Patent Application No. 10-2024-0156012 filed on Nov. 6, 2024, which is hereby incorporated by reference in its entirety.

### TECHNICAL FIELD

The present disclosure relates to an apparatus for manufacturing a display panel, and more specifically, to an apparatus for manufacturing a display panel, which transfers a light-emitting diode (LED) to a display panel.

### BACKGROUND

Recently, display devices including a light-emitting diode (LED) have been attracting attention as next-generation display devices. Since an LED is formed of an inorganic material rather than an organic material, the display devices including the LED have a faster turn-on speed, better luminous efficiency, and higher luminance images than LCD devices or OLED display devices.

These LEDs are transferred onto the display panel through a transfer member, but some remain on the transfer member or at an edge of the transfer member due to a transfer error.

The LEDs that remain on the transfer member in this way fall on a donor member during the next transfer process, thereby damaging the donor member or fall on the display panel, thereby causing a panel defect.

### SUMMARY

Accordingly, inventors of the present disclosure have invented an apparatus for manufacturing a display panel in which it is possible to prevent or at least reduce light-emitting elements from remaining on a transfer member during a transfer process, thereby preventing damage to a donor member or a panel defect.

Implementations of the present disclosure are directed to providing an apparatus for manufacturing a display panel in which, by allowing light-emitting members that remain on a transfer member during a transfer process to be adhered to a preventative maintenance wafer, it is possible to remove the light-emitting elements that remain on the transfer member.

Objects of the present disclosure are not limited to the above-described objects, and other objects and advantages of the present disclosure that are not mentioned can be understood by the following description and more clearly understood by implementations of the present disclosure. In addition, it will be able to be easily seen that the objects and advantages of the present disclosure can be achieved by devices and combinations thereof that are described in the claims.

In an apparatus for manufacturing a display panel according to one embodiment of the present disclosure, by forming a transfer portion of a transfer member to correspond to a storing portion of a wafer substrate and forming an edge portion of the transfer member to correspond to an outer portion of the wafer substrate, light-emitting elements that remain on the transfer member during a transfer process can be removed by being adhered to the storing portion and the outer portion of the wafer substrate.

### BRIEF DESCRIPTION OF DRAWINGS

FIG. 1 is a schematic view illustrating the overall configuration of an apparatus for manufacturing a display panel according to an embodiment of the present disclosure.

FIG. 2 is a plan view illustrating an example of a configuration of a transfer member illustrated in FIG. 1 according to an embodiment of the present disclosure.

FIG. 3 is a plan view illustrating an example of a configuration of a wafer substrate illustrated in FIG. 1 according to an embodiment of the present disclosure.

FIG. 4 is a cross-sectional view along line A-A′ in FIG. 3 with respect to the wafer substrate according to an embodiment of the present disclosure.

FIG. 5 is a view illustrating an area of a transport member corresponding to the transfer member according to an embodiment of the present disclosure.

FIG. 6 is a view illustrating an example in which the transfer member picks up a light-emitting element according to an embodiment of the present disclosure.

FIG. 7 is a view illustrating an example in which a light-emitting element remains on the transfer member during a transfer process according to an embodiment of the present disclosure.

FIG. 8 is a view illustrating an example in which light-emitting elements that remain on the transfer member are removed by being attached to the wafer substrate during the transfer process according to the embodiment of the present disclosure.

FIG. 9 is a plan view illustrating an example in which a plurality of light-emitting elements are adhered on the wafer substrate according to an embodiment of the present disclosure.

FIG. 10 is a cross-sectional view along line B-B′ in FIG. 9 with respect to the wafer substrate according to an embodiment of the present disclosure.

### DETAILED DESCRIPTION

Advantages and features of the present disclosure and methods for achieving them will become clear with reference to implementations described below in detail in conjunction with the accompanying drawings. However, the present disclosure is not limited to implementations to be disclosed below but may be implemented in various different forms, these implementations are merely provided to make the disclosure of the present specification complete and fully inform those skilled in the art to which the present disclosure pertains of the scope of the present disclosure, and the present disclosure is only defined by the scope of the appended claims.

Since shapes, sizes, ratios, angles, numbers, etc. disclosed in the drawings for describing the implementations of the present disclosure are exemplary, the present disclosure is not limited to the illustrated items. The same reference number denotes the same components throughout the specification. In addition, in describing the present disclosure, when it is determined that the detailed description of a related known technology may unnecessarily obscure the gist of the present disclosure, the detailed description thereof will be omitted. When “comprises,” “has,” “includes,” etc. described in the present disclosure are used, other parts may be added unless “only” is used. When a component is expressed in a singular form, it includes a case in which the component is provided as a plurality of components unless specifically stated otherwise.

In construing a component, the component is construed as including a margin of error even when there is no separate explicit description related to the margin of error.

When the positional relationship is described, for example, when the positional relationship between two parts is described using “on,” “above,” “under,” “next to,” or the like, one or more other parts may be located between the two parts unless “immediately” or “directly” is used.

When the temporal relationship is described, when the temporal relationship is described using the term “after,” “subsequently,” “then,” “before,” or the like, it may also include a non-consecutive case unless the term “immediately” or “directly” is used.

Although terms such as first and second are used to describe various components, these components are not limited by these terms. These terms are only used to distinguish one component from another component. Therefore, a first component described below may be a second component within the technical spirit of the present disclosure.

In the description of the components of the present disclosure, terms such as first A, B, (a), (b), etc. may be used. These terms are only for the purpose of distinguishing one component from another component, and the nature, sequence, order, or the like of the corresponding component is not limited by these terms. When a certain component is described as being “connected,” “coupled,” or “joined” to another component, the certain component may be connected or joined directly to another component, but it should be understood that other components may be “interposed” between the components, which may be connected or coupled indirectly, unless otherwise stated specially.

It should be understood that the term “at least one” includes any combination of one or more of associated components. For example, the term “at least one of first, second, and third components” may include not only the first, second, or third component, but also any combination of two or more of the first, second, and third components.

In the present disclosure, “apparatus” may include a display apparatus, such as a liquid crystal module (LCM) and an organic light emitting display module (OLED module), including a display panel and a driver for driving the display panel. In addition, the apparatus may also include a set electronic apparatus or a set device (or a set apparatus), such as a laptop computer, a television, a computer monitor, a vehicle or automotive apparatus, a mobile electronic apparatus of a smartphone, an electronic pad, etc., which is a complete product or final product including an LCM, an OLED, etc.

Accordingly, the apparatus in the present disclosure may include a display apparatus, such as an LCM or OLED module, and a set apparatus that is an application product or end-consumer apparatus including an LCM or OLED module, etc.

In addition, in some implementations, an LCM or OLED module that are composed of a display panel, a driving unit, etc. may be referred to as a “display apparatus,” and an electronic apparatus as a finished product including an LCM or OLED module may be separately referred to as a “set apparatus.” For example, the display apparatus may include a display panel of an LCD or an OLED, and a source printed circuit board (PCB) as a control unit for driving the display panel. The set apparatus may further include a set PCB as a set control unit electrically connected to the source PCB to drive the entirety of the set apparatus.

The display panel used in the implementations of the present disclosure may be any type of display panel, such as an OLED display panel, an electroluminescent display panel, etc. Implementations are not limited thereto. For example, the display panel may be a display panel that may generate sound by being vibrated by a vibration apparatus according to the embodiment of the present disclosure. The shape or size of the display panel applied to the display apparatus according to implementations of the present disclosure is not limited.

The respective features of various implementations of the present disclosure may be coupled or combined partially or entirely, various technological interworking and driving are made possible, and the implementations may be implemented independently of each other or implemented together in an associated relationship.

Hereinafter, implementations of the present disclosure will be described with reference to the accompanying drawings and implementations as follows. Scales of components illustrated in the drawings differ from the actual scale for convenience of description, and thus are not limited to the scales illustrated in the drawings.

Hereinafter, as one embodiment of the present disclosure, a display apparatus using a micro LED as a light-emitting element will be described.

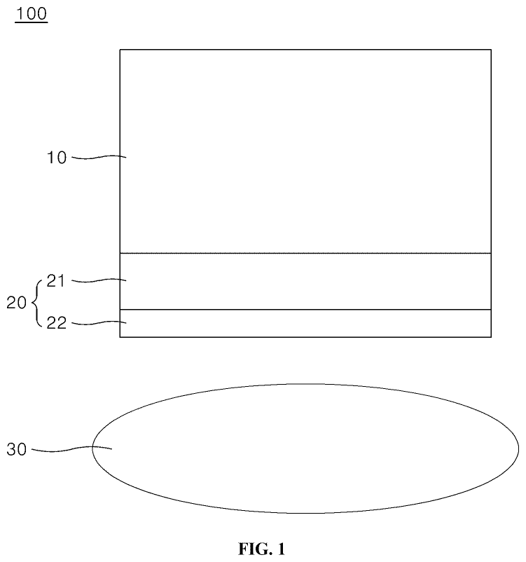

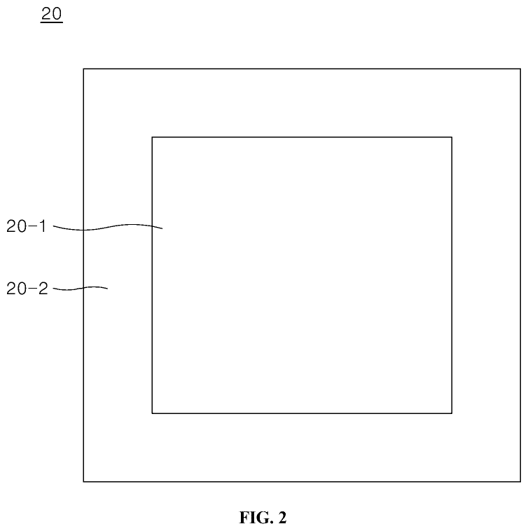

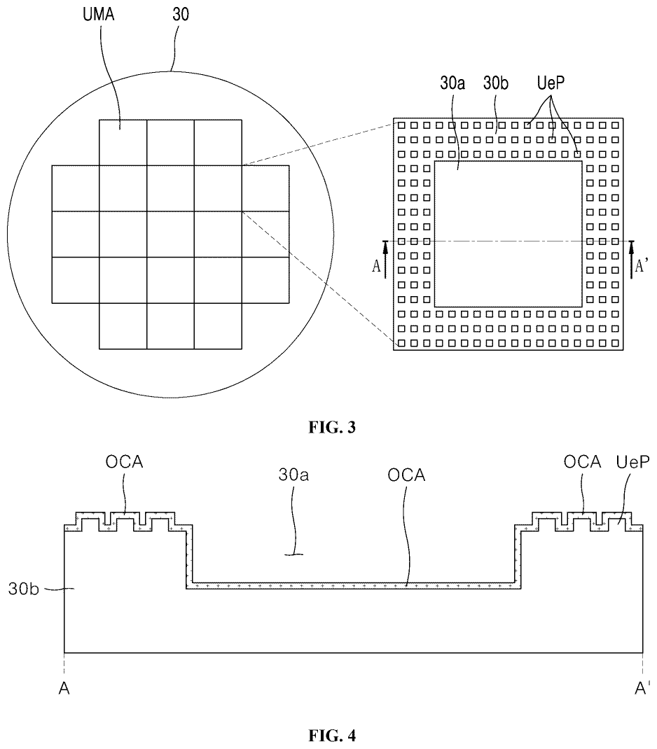

FIG. 1 is a schematic view illustrating the overall configuration of an apparatus for manufacturing a display panel according to an embodiment of the present disclosure. FIG. 2 is a plan view illustrating an example of a configuration of a transfer member illustrated in FIG. 1 according to an embodiment of the present disclosure. FIG. 3 is a plan view illustrating an example of a configuration of a wafer substrate illustrated in FIG. 1 according to an embodiment of the present disclosure.

Referring to FIGS. 1 to 3, an apparatus 100 for manufacturing a display panel according to the embodiment of the present disclosure may include a transport member 10, a transfer member 20, and a wafer substrate 30.

The transport member 10 may be used to transport the transfer member 20.

The transfer member 20 may include a transfer portion 20-1 in which a plurality of light-emitting elements to be transferred onto the display panel are aligned and disposed, and an edge portion 20-2 surrounding the transfer portion 20-1 as shown in FIG. 2.

The transfer member 20 may be formed of a material that transmits a laser.

The wafer substrate 30 is a preventive maintenance wafer (PMW) used to remove light-emitting elements that remain on the transfer member 20 after the transfer process. Accordingly, the wafer substrate may be referred to as a “maintenance substrate” or a “maintenance wafer.”

The wafer substrate 30 may include a storing portion 30a that accommodates or stores some of the plurality of light-emitting elements and an outer portion 30b surrounding the storing portion 30a as shown in FIG. 3. The storing portion 30a may be referred to as an “accommodating portion.”

The wafer substrate 30 may include an active area and a non-active area.

A plurality of units of maintenance area UM A may be disposed in a matrix form in the active area 30a as illustrated in FIG. 3. Each unit of maintenance area UM A may include the storing portion 30a and the outer portion 30b.

The transfer member 20 may include a base layer 21 and a stamp layer 22 disposed on one surface of the base layer 21 as shown in FIG. 1.

The base layer 21 may be formed of, for example, glass or plastic. When the base layer 21 includes thin glass, the glass may be ultra thin glass. Alternatively, the base layer 21 may be formed of polyethylene terephthalate (PET), polyurethane (PU), polyimide (PI), polycarbonate (PC), polyethylene (PE), polypropylene (PP), polysulfone (PSF), polymethyl methacrylate (PMMA), triacetyl cellulose (TAC), cycloolefin polymer (COP), etc.

The stamp layer 22 may be formed of an adhesive or sticky material. The adhesive material may include, for example, an optical clear adhesive (OCA), a pressure sensitive adhesive (PSA), etc., and the sticky material may include, for example, an acryl-based, urethane-based, or silicon-based adhesive material. The stamp layer 22 may be formed to be thinner than the base layer 21.

The stamp layer 22 may be disposed on one surface of the base layer 21 and stuck or adhered to a light-emitting element LED to be described below.

The light emitting element LED may include a micro light-emitting diode (LED). The micro LED may be formed to a size of about 10 μm to 100 μm. Although not illustrated in the drawings, the micro LED may be manufactured by forming a buffer layer on a substrate and growing a GaN thin film on the buffer layer. In this case, sapphire, silicon (si), GaN, silicon carbide (SiC), gallium arsenide (GaAs), zinc oxide (ZnO), etc. may be used as the substrate for growing a GaN thin film. In the embodiment of the present disclosure, for example, a sapphire substrate may be applied as the substrate for growing a GaN thin film.

In addition, when the substrate for growing a GaN thin film is formed of a material other than a GaN substrate, the buffer layer may be formed of AlN, GaN, etc. to prevent or at least reduce quality from being degraded by lattice mismatch that occurs when growing a n-type GaN layer, which is an epi layer, directly on a substrate.

The n-type GaN layer may be formed by growing an undoped GaN layer and then doping an n-type impurity, such as Si, on an undoped thin film. In addition, ap-type GaN layer may be formed by growing an undoped GaN thin film and then doping a p-type impurity, such as M g, Zn, or Be.

Meanwhile, although not illustrated in the drawings, the transport member 10 may include a transport head, a head chuck, and a laser transmissive portion. The head chuck may detach the transfer member 20. The laser transmissive portion may transmit laser and heat and press the light-emitting element LED during a bonding process of the light-emitting element LED.

In addition, although not illustrated in the drawings, the apparatus 100 for manufacturing a display panel according to the embodiment of the present disclosure may further include a control unit (e.g., a circuit) and a heating member.

The control unit may control other components. For example, the control unit may move the transport member 10 to a desired location in a first direction (e.g., X), a second direction (e.g., Y), and a third direction (e.g., Z). As another example, the control unit may control adsorption and detachment of the head chuck. For convenience of description, the control of the control unit is not described, but components may be described as performing an operation, for example, the transport member 10 moving, or the head chuck of the transport member 10 being adsorbed to or detached from the transfer member 20.

The heating member may provide heat for bonding the light-emitting element LED. For example, the heating member may provide laser irradiation to the light-emitting element LED through the laser transmissive portion and the transfer member 20. Accordingly, the light emitting element LED may be pressed, melted, and bonded.

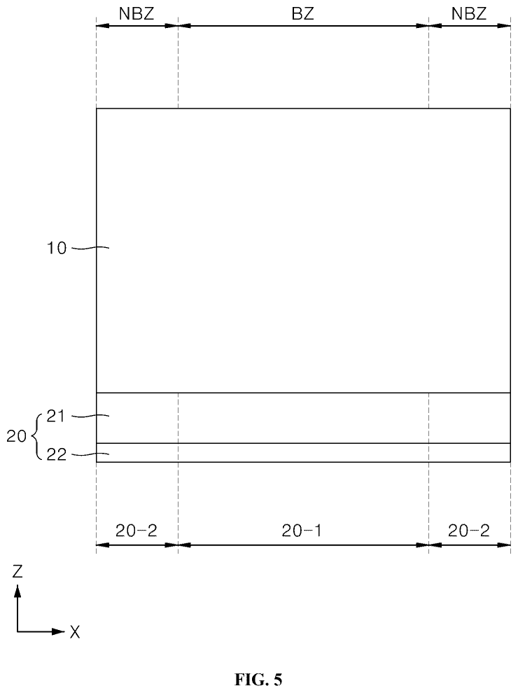

FIG. 4 is a cross-sectional view along line A-A′ in FIG. 3 with respect to the wafer substrate according to an embodiment of the present disclosure.

Referring to FIG. 4, the wafer substrate 30 according to the embodiment of the present disclosure may include the storing portion 30a and the outer portion 30b disposed outside the storing portion 30a.

The storing portion 30a has a groove shape having a predetermined depth, and a surface of the storing portion 30a may be lower than a surface of the outer portion 30b. Accordingly, the storing portion 30a and the outer portion 30b may have a stepped structure.

The outer portion 30b may have an upper surface with a shape of a regular uneven pattern UeP.

An adhesive material or a sticky material may be applied to each of an upper surface of the groove of the storing portion 30a and an upper surface of the uneven pattern UeP of the outer portion 30b. An adhesive material or a sticky material may also be applied to both inner sidewalls of the groove of the storing portion 30a. The uneven pattern UeP may have a structure formed by repeatedly alternating concave and convex shapes.

The adhesive material may include, for example, an optical clear adhesive (OCA), a pressure sensitive adhesive (PSA), etc., and the sticky material may include, for example, an acryl-based, urethane-based, or silicon-based adhesive material.

FIG. 5 is a view illustrating an area of a transport member corresponding to the transfer member according to an embodiment of the present disclosure.

Referring to FIG. 5, the transfer member 20 according to the embodiment of the present disclosure may have the transfer portion 20-1 disposed at a central portion thereof, and the edge portion 20-2 disposed at both outer sides of the transfer portion 20-1.

The transport member 10 corresponding to the transfer member 20 may have a bonding zone BZ disposed at a central portion thereof and non-bonding zones N B Z disposed at both outer sides of the bonding zone BZ.

In this case, the transfer portion 20-1 may correspond to the bonding zone B Z, and the edge portion 20-2 may correspond to the non-bonding zone NBZ.

Accordingly, the transfer portion 20-1 may overlap the bonding zone BZ, and the edge portion 20-2 may overlap the non-bonding zone NBZ.

In addition, the transfer member 20 may include the base layer 21 and the stamp layer 22, and the stamp layer 22 may overlap the bonding zone BZ and may not overlap the non-bonding zones NB Z.

The transfer portion 20-1 may include the base layer 21 and the stamp layer 22 while the edge portion 20-2 may include only the base layer 21.

The transfer portion 20-1 may overlap the bonding zone BZ and may not overlap the non-bonding zones NBZ. The edge portion 20-2 may overlap the non-bonding zones NBZ and may not overlap the bonding zone BA.

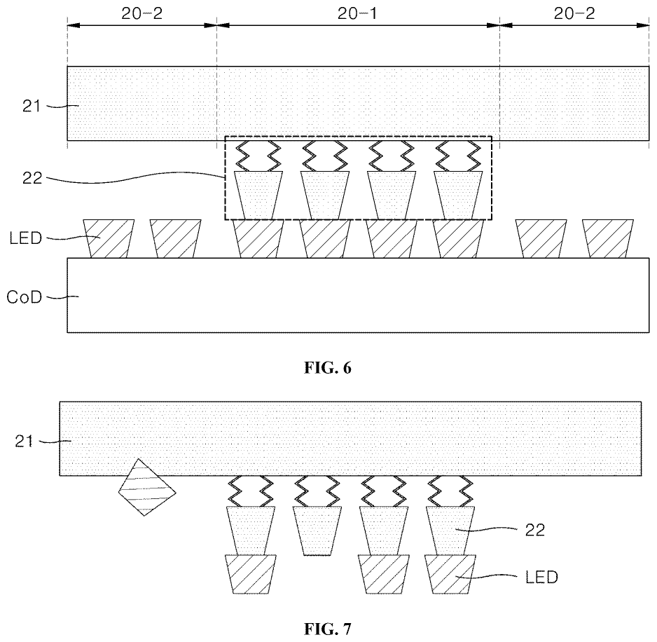

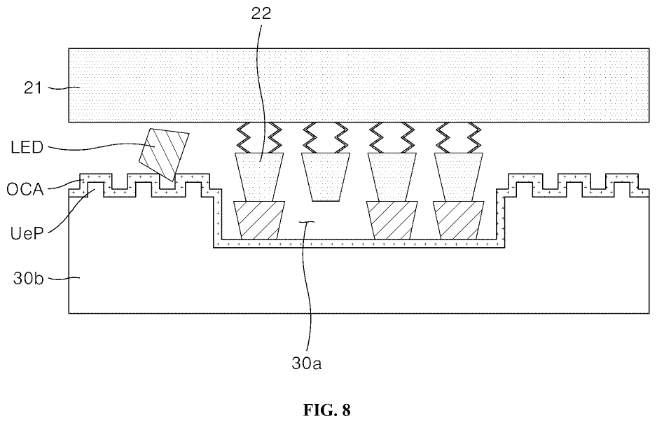

FIG. 6 is a view illustrating an example in which the transfer member picks up a light-emitting element according to an embodiment of the present disclosure. FIG. 7 is a view illustrating an example in which a light-emitting element remains on the transfer member during a transfer process according to an embodiment of the present disclosure. FIG. 8 is a view illustrating an example in which light-emitting elements that remain on the transfer member are removed by being attached to the wafer substrate during the transfer process according to an embodiment of the present disclosure.

Referring to FIG. 6, a plurality of light-emitting elements LED according to the embodiment of the present disclosure as a transfer target may be detached from a chip on donor CoD through the transfer member 20 and then transferred onto the display panel.

The transfer member 20 may be provided so that the base layer 21 corresponds to an area including the transfer portion 20-1 and the edge portion 20-2, and the stamp layer 22 may be provided in an area corresponding to the transfer portion 20-1.

The plurality of light-emitting elements LED may be arranged and disposed on the chip on donor CoD. The chip on donor CoD may be called a donor substrate CoD.

The stamp layer 22 may have a spring structure. Accordingly, the stamp layer 22 may have an elastic force.

The stamp layer 22 may have a surface that faces the plurality of light-emitting elements LED and is covered with an adhesive material or a sticky material. Accordingly, the stamp layer 22 may be adhered or stuck to the plurality of light-emitting elements LED by an adhesive material or a sticky material, thereby picking up the plurality of light-emitting elements LED.

Although not illustrated, a protective film may be attached to one surface of the stamp layer 22. The protective film may be formed of, for example, glass or plastic. When the protective film includes thin glass, the glass may be ultra thin glass.

Before the transfer member 20 picks up the plurality of light-emitting elements LED through the stamp layer 22, the protective film attached to the one surface of the stamp layer 22 may be peeled from the stamp layer 22.

The transfer member 20 may be transported onto the chip on donor CoD by the transport member 10. The transport member 10 may move to pick up and transport the transfer member 20 disposed on a support member (not illustrated). The support member serves to support a plurality of transfer members 20. The plurality of transfer members 20 may be aligned and disposed on the support member.

The protective film is removed in a state in which the transfer member 20 is picked up and held by the transport member 10, and the transport member 10 picks up the plurality of light-emitting elements LED from the chip on donor CoD using the transfer member 20.

In this case, first, the chip on donor CoD on which the plurality of light-emitting elements LED are aligned and arranged is provided. The chip on donor CoD may be covered with a sticky material. The chip on donor CoD and the plurality of light-emitting elements LED may be stuck by the sticky material.

The transport member 10 transports the picked-up transfer member 20 to the chip on donor CoD and adheres the light-emitting elements LED to one surface of the transfer member 20.

Thereafter, the transfer member 20 is moved in the third direction (the Z-axis direction) to detach the plurality of light-emitting elements LED from the chip on donor CoD.

To detach the light-emitting elements LED from the chip on donor CoD using the transfer member 20, a sticky force (or a bonding force) between the stamp layer 22 of the transfer member 20 and the light-emitting elements LED needs to be greater than a sticky force (or a bonding force) between the chip on donor CoD and the light-emitting elements LED.

In addition, the transport member 10 needs to apply a tensile force, which is greater than the bonding force (or the bonding force) between the chip on donor CoD and the light-emitting elements LED in the third direction (the Z-axis direction), to the transfer member 20.

Referring to FIG. 7, when the transfer member 20 detaches the plurality of light-emitting elements LED from the chip on donor CoD, some of the plurality of light-emitting elements LED may be adhered to the transfer portion 20-1 of the stamp layer 22, and others may be adhered to the edge portion 20-2 of the base layer 21.

In this case, the stamp layer 220 may be stuck or adhered to light-emitting elements LED that remain after being transferred onto the display panel or light-emitting elements in which a transfer error has occurred among the plurality of light-emitting elements LED.

Referring to FIG. 8, the transfer member 20 may move the light-emitting elements LED, which remain after being transferred onto the display panel or in which a transfer error has occurred and which are adhered to the transfer portion 20-1 and the edge portion 20-2, to the wafer substrate 30 and adhere the light-emitting elements LED to the storing portion 30a and the outer portion 30b.

A depth of the storing portion 30a may be the same as a height of the light-emitting element LED or may have a depth greater than the height of the light-emitting element LED.

In the wafer substrate 30, the storing portion 30a may correspond to the transfer portion 20-1, and the outer portion 30b may correspond to the edge portion 20-2.

In this case, each of the storing portion 30a and the outer portion 30b may have a surface covered with an adhesive material or a sticky material (OCA).

Accordingly, the light-emitting elements LED stuck or adhered to the transfer portion 20-1 may be stuck or adhered to the storing portion 30a, and the light-emitting elements LED stuck or adhered to the edge portion 20-2 may be stuck or adhered to the outer portion 30b.

Here, the bonding force between the storing portion 30a and the light-emitting elements LED may be greater than the bonding force between the transfer portion 20-1 and the light-emitting elements LED.

Here, the bonding force between the outer portion 30b and the light-emitting elements LED may be greater than the bonding force between the edge portion 20-2 and the light-emitting elements LED.

Each of the plurality of light-emitting elements LED may include a first sub-element that emits light of a first color, a second sub-element that emits light of a second color, and a third sub-element that emits light of a third color. Each of the light-emitting elements LED may further include a fourth sub-element that emits light of a fourth color.

For example, when the first color is red, the second color may be green, the third color may be blue, and the fourth color may be white. Each of the first color, the second color, the third color, and the fourth color may be one of red (R), green (G), blue (B), and white (W).

One or more sub-elements of each of the plurality of light-emitting elements LED may be detached from the chip on donor CoD and transferred onto the display panel through the transfer member 20.

Sub-elements of some of the plurality of light-emitting elements LED may remain by being attached to the transfer portion 20-1 and the edge portion 20-2 of the transfer member 20 due to a transfer error, but may be removed from the transfer member 20 by being adhered to the storing portion 30a and the outer portion 30b of the wafer substrate 30.

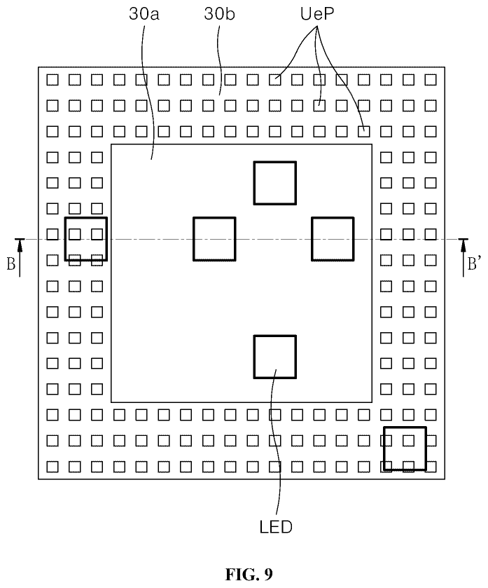

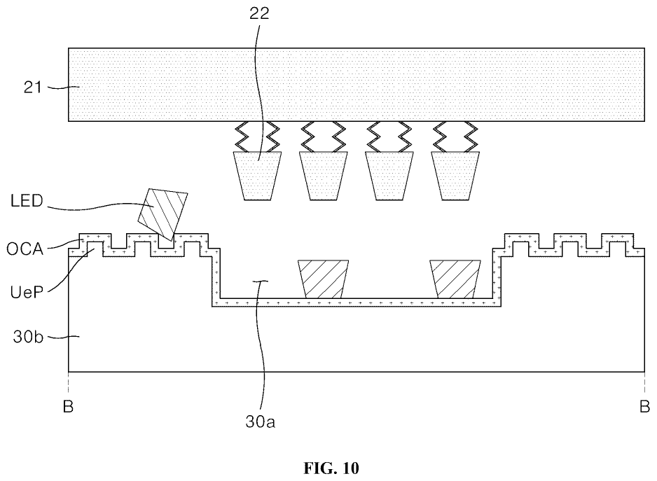

FIG. 9 is a plan view illustrating an example in which a plurality of light-emitting elements are adhered on the wafer substrate according to an embodiment of the present disclosure. FIG. 10 is a cross-sectional view along line B-B′ in FIG. 9 with respect to the wafer substrate according to an embodiment of the present disclosure.

Referring to FIGS. 9 and 10, some of the plurality of light-emitting elements LED detached from the transfer member 20 may be stuck or adhered to the storing portion 30a of the wafer substrate 30, and the others may be stuck or adhered to the outer portion 30b.

A plurality of uneven patterns UeP are formed on the outer portion 30b of the wafer substrate 30. Accordingly, the others of the plurality of light-emitting elements LED may be stuck or adhered on the uneven patterns UeP of the outer portion 30b.

The storing portion 30a of the wafer substrate 30 may have an area that is greater than or equal to an area of the transfer portion 20-1 of the transfer member 20.

The outer portion 30b of the wafer substrate 30 may have an area that is greater than or equal to an area of the edge portion 20-2 of the transfer member 20.

During the transfer process, the plurality of light-emitting elements LED adhered to the transfer member 20 due to a transfer error may be detached from the transfer member 20 and stuck or adhered to the wafer substrate 30. This is because the bonding force between the storing portion 30a and the light-emitting elements LED is greater than the bonding force between the transfer portion 20-1 and the light-emitting elements LED and the bonding force between the outer portion 30b and the light-emitting elements LED is greater than the bonding force between the edge portion 20-2 and the light-emitting elements LED.

Meanwhile, each of the plurality of light-emitting elements LED detached from the chip on donor CoD and successfully transferred onto the display panel by the transfer member 20 may include a bonding electrode although not illustrated.

The bonding electrode may be a bonding product of pressing, melting, and bonding using a laser, etc.

The transfer member 20 may transfer the light-emitting elements LED picked up from the chip on donor CoD onto the display panel and bond the light-emitting elements LED on a circuit board (not illustrated). A flux of a predetermined thickness may be applied to the circuit board. The flux may be a material that facilitates bonding between the circuit board and the bonding electrode during a pressing and melting process using a laser. The flux may be oil-soluble or water-soluble and may include natural or synthetic rosin. The flux may be in a liquid or gel form. After the pressing and melting process is completed, the flux is removed.

The light-emitting element LED, which will be bonded, is disposed on the circuit board, and the bonding electrode is disposed on one surface of the light-emitting element LED, which comes into contact with the circuit board. The transfer member 20 is disposed on the other surface of the light-emitting element LED so that the light-emitting element LED overlaps the transfer member 20.

In addition, the laser transmissive portion (not illustrated) of the transport member 10 overlaps the transfer member 20. Accordingly, the bonding electrode, the light-emitting element LED, the transfer member 20, and the laser transmissive portion overlap each other in the bonding zone BZ of FIG. 5.

The transfer member 20 overlaps both the bonding zone BZ and the non-bonding zone NBZ. The transfer member 20 may have the transfer portion 20-1 that overlaps the bonding zone and the edge portion 20-2 that overlaps the non-bonding zone NBZ. As described above, since the non-bonding zone NB Z may surround the bonding zone BZ in a plan view, the edge portion 20-2 may also be formed to surround the transfer portion 20-1 in a plan view.

When the transfer member 20 picks up the light-emitting element LED from the chip on donor CoD, the light-emitting element LED is bonded to both the transfer portion 20-1 and the edge portion 20-2 of the transfer member 20.

Since the edge portion 20-2 is non-overlapping with the bonding zone BZ, the light-emitting element LED bonded to the edge portion 20-2 is not bonded on the circuit board. The light-emitting element LED adhered to the edge portion 20-2 is removed by being stuck or adhered to the outer portion 30b of the wafer substrate 30 as described above.

As the heating member radiates a laser to the bonding electrode in a state in which the transport member 10 presses the transfer member 20, the laser may be irradiated to the bonding electrode after passing through the laser transmissive portion and the transfer member 20.

Accordingly, the heating member may apply heat to the bonding electrode up to a melting temperature of the bonding electrode, thereby pressing, melting, and bonding the circuit board and the bonding electrode. Here, the pressing, melting, and bonding refers to a state in which the bonding electrode is heated and melted by the laser irradiation, mixed with the light-emitting element LED, an anode pad electrode, and a cathode pad electrode, which are melted, and then cooled and solidified when the laser supply is finished. Since conductivity by the light-emitting element LED, the anode pad electrode, and the cathode pad electrode is maintained even while the bonding electrode is cooled and solidified in a melted and mixed state, the anode pad electrode, the cathode pad electrode, and the light-emitting element LED may be electrically and physically connected.

As described above, according to the embodiment of the present disclosure, it is possible to achieve the apparatus for manufacturing a display panel in which, since the transfer portion of the transfer member is formed to correspond to the storing portion of the wafer substrate, and the edge portion of the transfer member is formed to correspond to the outer portion of the wafer substrate, the light-emitting elements that remain on the transfer member during the transfer process may be removed by being adhered to the storing portion and the outer portion of the wafer substrate.

An apparatus for manufacturing a display panel according to implementations of the present disclosure may be described as follows.

An apparatus for manufacturing a display panel according to an embodiment of the present disclosure may include a transfer member including a transfer portion in which a plurality of light-emitting elements to be transferred onto a display panel are aligned and disposed and an edge portion surrounding the transfer portion, and a wafer substrate including a storing portion that stores some of the plurality of light-emitting elements and an outer portion surrounding the storing portion.

According to some implementations of the present disclosure, the storing portion may have a groove shape having a predetermined depth, and a surface of the storing portion may be lower than a surface of the outer portion.

According to some implementations of the present disclosure, the outer portion may have an upper surface with a shape of a predetermined uneven pattern UeP.

According to some implementations of the present disclosure, a depth of the storing portion may be a depth that is equal to or greater than a height of the light-emitting element.

According to some implementations of the present disclosure, an adhesive material or a sticky material may be applied to each of an upper surface of the groove of the storing portion and an upper surface of the uneven pattern of the outer portion.

According to some implementations of the present disclosure, the wafer substrate may include an active area and a non-active area, a plurality of units of maintenance area UM A may be disposed in a matrix form in the active area, and each unit of maintenance area may include the storing portion and the outer portion.

According to some implementations of the present disclosure, the transfer member may include a base layer 21 and a stamp layer 22 disposed on one surface of the base layer.

According to some implementations of the present disclosure, a surface of the stamp layer may be covered with an adhesive material or a sticky material.

According to some implementations of the present disclosure, the stamp layer may be stuck or adhered to a light-emitting element which remains after being transferred onto the display panel or a light-emitting element in which a transfer error has occurred among the plurality of light-emitting elements.

According to some implementations of the present disclosure, the storing portion may correspond to the transfer portion, and the outer portion may correspond to the edge portion.

According to some implementations of the present disclosure, the transfer member may move light-emitting elements, which remain after being transferred onto the display panel or in which a transfer error has occurred and which are adhered to the transfer portion and the edge portion, to the wafer substrate and adhere the light-emitting elements to the storing portion and the edge portion.

According to some implementations of the present disclosure, the storing portion may have an area that is equal to or greater than an area of the transfer portion, and the outer portion may have an area that is equal to or greater than an area of the edge portion.

According to some implementations of the present disclosure, a bonding force between the stamp layer 22 and the light-emitting element LED may be greater than a bonding force between the light-emitting element LED and the chip on donor CoD.

According to some implementations of the present disclosure, a surface of each of the storing portion 30a and the outer portion 30b may be covered with an adhesive material or a sticky material.

According to some implementations of the present disclosure, the bonding force between the storing portion 30a and the light-emitting element LED may be greater than the bonding force between the transfer portion 20-1 and the light-emitting element LED, and the bonding force between the outer portion 30b and the light-emitting element LED may be greater than the bonding force between the edge portion 20-2 and the light-emitting element LED.

According to the implementations of the present disclosure, by allowing the light-emitting members that remain on the transfer member during the transfer process to be adhered to the preventative maintenance wafer, it is possible to remove the light-emitting elements that remain on the transfer member.

In addition, according to the implementations of the present disclosure, by removing the light-emitting elements that remain on the transfer member during the transfer process, it is possible to prevent damage to the donor member or the panel defect.

In addition, according to the implementations of the present disclosure, it is possible to prevent damage to the donor member or the panel defect, thereby improving quality of the display device.

In addition, according to the implementations of the present disclosure, by improving the defect of the display panel, it is possible to prevent the life of the panel from being reduced.

In addition, according to the implementations of the present disclosure, by preventing the panel defect so that the display panel is operated without any failure, it is possible to provide the long-life and low-power display device.

Effects of the present disclosure are not limited to the above-described effects, and other effects that are not described will be able to be clearly understood by those skilled in the art based on the following description.

Specific effects of the present disclosure along with the above-described effects are described along with the description of the following detailed matters for carrying out implementations of the disclosure.

Although the present disclosure has been described above with reference to the exemplary drawings, the present disclosure is not limited by the implementations and drawings disclosed in the present disclosure, and it is apparent that various modifications can be made by those skilled in the art within the scope of the technical spirit of the present disclosure. In addition, even when the operational effects according to the configuration of the present disclosure have not been explicitly described in the description of the implementations of the present disclosure, it is apparent that the effects predictable by the corresponding configuration should also be recognized.

### DESCRIPTION OF REFERENCE NUMERALS

100: apparatus for manufacturing a display panel,
10: transport member
20: transfer member 20-1: transfer portion
20-2: edge portion 21: base layer
22: stamp layer 30: wafer substrate
30a: storing portion 30b: outer portion
UMA: unit of maintenance area UeP: uneven pattern
OCA: optical clear adhesive BZ: bonding zone
NBZ: non-bonding zone LED: light-emitting element
R, G, B: sub-element CoD: chip on donor

What is claimed:

1. An apparatus for manufacturing a display panel, comprising:
a transfer member including a transfer portion in which a plurality of light-emitting elements to be transferred on the display panel are aligned and disposed, and an edge portion surrounding the transfer portion; and
a wafer substrate including a storing portion that accommodates some of the plurality of light-emitting elements and an outer portion surrounding the storing portion.

2. The apparatus of claim 1, wherein the storing portion has a groove shape having a predetermined depth and a surface of the storing portion is lower than a surface of the outer portion.

3. The apparatus of claim 2, wherein the outer portion has a concave and convex pattern on an upper surface of the outer portion.

4. The apparatus of claim 2, wherein a depth of the storing portion is equal to or greater than a height of a light-emitting element from the plurality of light-emitting elements.

5. The apparatus of claim 3, wherein each of an upper surface of the groove shape of the storing portion and the upper surface of the outer portion are covered with an adhesive material or a sticky material.

6. The apparatus of claim 1, wherein the wafer substrate includes an active area and anon-active area,
wherein a plurality of units of maintenance area are disposed in a matrix form in the active area, each of the plurality of units of maintenance area includes the storing portion and the outer portion.

7. The apparatus of claim 1, wherein the transfer member includes a base layer and a stamp layer on surface of the base layer.

8. The apparatus of claim 7, wherein a surface of the stamp layer is covered with an adhesive material or a sticky material.

9. The apparatus of claim 8, wherein the stamp layer is stuck or adhered to a light-emitting element that remains after being transferred onto the display panel or a light-emitting element with transfer error.

10. The apparatus of claim 1, wherein the storing portion corresponds to the transfer portion and the outer portion corresponds to the edge portion.

11. The apparatus of claim 10, wherein the transfer member is configured to move light-emitting elements from the plurality of light-emitting elements, which remain after being transferred onto the display panel or in which a transfer error has occurred and which are adhered to the transfer portion and the edge portion, to the wafer substrate and adheres the light-emitting elements to the storing portion and the edge portion.

12. The apparatus of claim 1, wherein the storing portion has an area that is equal to or greater than an area of the transfer portion, and the outer portion has an area that is equal to or greater than an area of the edge portion.

13. The apparatus of claim 9, wherein a bonding force between the stamp layer and the light-emitting element is greater than a bonding force between the light-emitting element and a donor substrate.

14. The apparatus of claim 11, wherein a surface of each of the storing portion and the outer portion is covered with an adhesive material or a sticky material.

15. The apparatus of claim 14, wherein a bonding force between the storing portion and a light-emitting element from the plurality of light-emitting elements is greater than a bonding force between the transfer portion and the light-emitting element, and a bonding force between the outer portion and the light-emitting element is greater than a bonding force between the edge portion and the light-emitting element.
